(19) United States
(12) Patent Application Publication
(10) Pub. No.: US 2007/0284091 A1
(43) Pub. Date: Dec. 13, 2007

(54) Domed heat exchanger (igloo)

(76) Inventors: Debashis Ghosh, Williamsville, NY (US); Mohinder Singh Bhatti, Amherst, NY (US); David P. Rusch, Williamsville, NY (US)

Correspondence Address: DELPHI TECHNOLOGIES, INC., M/C 480-410-202, PO BOX 5052, TROY, MI, 48007, US

(21) Appl. No.: 11/439,063

(22) Filed: May 23, 2006

(51) Int. Cl. H05K 7/20

(52) U.S. Cl. 165/104.33; 165/121; 361/700

(57) ABSTRACT

A heat exchanger assembly for cooling an electronic device comprises a flange, a dome, a plurality of condensing tubes, a shroud and a boiler plate. The dome is semi-cylindrical in shape with flat axial ends. A plurality of spaced condensing tubes is disposed in a plurality of fan rows with each fan row being in a fan plane to facilitate more-efficient heat transfer. The distal ends of each of the condensing tubes are elongated along the associated fan plane to define the fan rows in a fan shape. In other words, each fan row contains one elongated, fan-shaped condensing tube. The condensing tubes in adjacent fan planes terminate in an arch extending concentrically about the center axis at the flat axial ends of the semi-cylindrical dome. The pattern of the elongated condensing tubes resembles the erectile ribs of an igloo.

### CROSS REFERENCE TO RELATED APPLICATION

This application discloses and claims one species of the broad concept of a domed heat exchanger. Co-pending application Ser. No. ______ filed ______ (DP-314799, 604080-6) discloses and claims the broad concept of a domed heat exchanger and another patentably distinct species.

### BACKGROUND OF THE INVENTION

1. Field of the Invention

The present invention relates to a heat exchanger assembly for cooling an electronic device.

2. Description of the Prior Art

The operating speed of computers is constantly being improved to create faster computers. With this improvement, comes increased heat generation and a need to effectively dissipate that heat.

Heat exchangers and heat sink assemblies have been used that apply natural or forced convection cooling methods to dissipate heat from electronic devices that are highly concentrated heat sources such as microprocessors and computer chips. These heat exchangers typically use air to directly remove heat from the electronic devices; however air has a relatively low heat capacity. Thus, liquid-cooled units called LCUs employing a cold plate in conjunction with high heat capacity fluids have been used to remove heat from these types of heat sources. Although LCUs are satisfactory for moderate heat flux, increasing computing speeds have required more effective heat sink assemblies.

Accordingly, thermosiphon cooling units (TCUs) have been used for cooling electronic devices having a high heat flux. A typical TCU absorbs heat generated by the electronic device by vaporizing the working fluid housed on the boiler plate of the unit. The boiling of the working fluid constitutes a phase change from liquid-to-vapor state and as such the working fluid of the TCU is considered to be a two-phase fluid. The vapor generated during boiling of the working fluid is then transferred to a condenser, where it is liquefied by the process of film condensation over the condensing surface of the TCU. The heat is rejected into a stream of air flowing through a tube running through the condenser or flowing over fins extending from the condenser. Alternatively, a second refrigerant can flow through the tube increasing the cooling efficiency. The condensed liquid is returned back to the boiler plate by gravity to continue the boiling-condensing cycle.

An example of a cooling system for electronic devices is disclosed in U.S. Pat. No. 6,085,831 to DiGiacomo et al.

The DiGiacomo patent discloses a TCU including a housing having a lower portion for holding a refrigerant and an upper portion having a top wall wherein heat transfer fins are disposed on the top wall. The upper portion of the housing includes a plurality of condensing chambers extending upwardly and outwardly along a single vertical plane from the lower portion of the housing. A TCU comprising a condenser and a boiling chamber is generally limited by the lack of space available for effective condensing. The boiling intensity of the refrigerant over the electronic device is generally high since the heat source is highly concentrated over the small area of the electronic device.

Although the prior art dissipates heat from electronic devices, as computing speeds increase, there is a continuing need for cooling devices having more efficient or alternative heat transfer capabilities as compared to the conventional electronic cooling assemblies.

### SUMMARY OF THE INVENTION AND ADVANTAGES

The invention provides for an orientation insensitive heat exchanger assembly including a boiler plate for disposition over and cooling an electronic device. The assembly includes a dome disposed on a boiler plate to define a boiling chamber that houses a refrigerant for undergoing a liquid-to-vapor-to-condensate cycle in response to the heat generated by the electronic device. A plurality of spaced condensing tubes is disposed in a plurality of fan rows and extends from the dome to distal ends. The distal ends of each of the condensing tubes are elongated along the associated fan plane to define one of the fan rows in a fan shape. In other words, each fan row contains one elongated, fan-shaped condensing tube. The shroud encloses the distal ends of the condensing tubes in spaced relationship to the dome for moving air through the condensing tubes and over the dome. The shroud and the distal ends of the condensing tubes are disposed in a domed shape in spaced relationship to the dome.

The present invention operates with a high fin efficiency. The assembly provides a high amount of condensing surface in a relatively small overall volume through the use of a multitude of curvilinear hollow tubes in the boiling chamber.

Additionally, the design of the present invention makes it readily scalable. The invention can easily be made to engage tiny computer chips as well as high-powered devices of large telecom towers.

### BRIEF DESCRIPTION OF THE DRAWINGS

Other advantages of the present invention will be readily appreciated, as the same becomes better understood by reference to the following detailed description when considered in connection with the accompanying drawings wherein:

FIG. 1 is a perspective view of the invention employing an overall semi-spherical shape with flat ends;

FIG. 2 is a diametrical cross-sectional view of the embodiment of FIG. 1 including a shroud and an air cooling assembly;

FIG. 3 is an exploded view of the embodiment of FIG. 2; and

FIG. 4 is a perspective view of the embodiment of FIG. 1 but with a shroud, shown in a cut-away view, and a closed liquid cooling assembly.

### DETAILED DESCRIPTION OF THE INVENTION

Referring to the Figures, wherein like numerals indicate corresponding parts throughout the several views, a heat exchanger assembly for cooling an electronic device 22 is shown. The assembly includes a flange 24, a dome 26, a plurality of condensing tubes 28, a shroud 30, and a boiler plate 32.

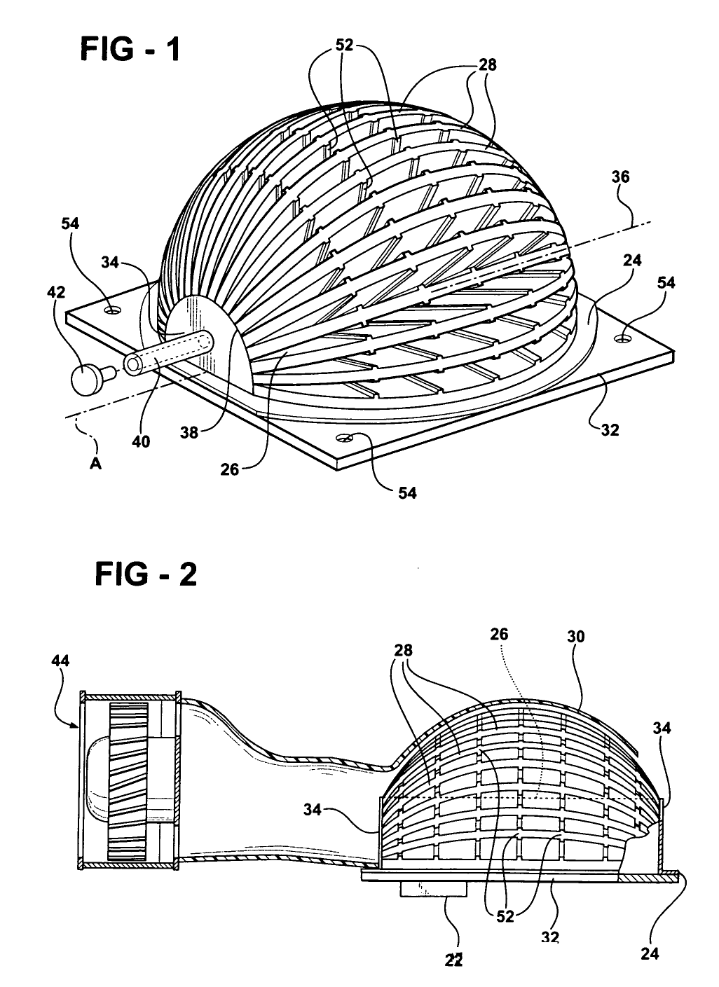

The dome 26 has a center axis A and includes a flange 24, although the dome 26 may be welded or otherwise secured directly to the boiler plate 32 as illustrated in FIG. 1. As illustrated, the flange 24 is disposed on the periphery of the dome 26. The flange 24 may be integral to the dome 26 or it may be separate and connected by brazing or a fastening device well known in the art. The lower edge of the dome 26 engages the boiler plate 32 and the inside edge of the flange 24, and may be brazed thereto. The dome 26 defines a domed boiling chamber curved axially along and laterally from the center axis A. The boiler plate 32 is flat and is disposed beneath the flange 24. The boiler plate 32 is disposed over the electronic device 22, as well known in the art. A refrigerant is disposed in the boiling chamber defined by the dome 26 to receive heat from the electronic device 22 and to boil into vapor that is condensed into the liquid in a plurality of condensing tubes 28.

As shown in FIG. 1, the dome 26 is semi-cylindrical in shape with flat axial ends 34. The distance measured axially along the center axis A is greater than the distance measured laterally from or perpendicular to the center axis A. In other words, the periphery of the semi-cylindrical dome 26 forms a rectangular shape over the boiler plate 32. When bisected transversely to the center axis A the dome 26 is divided into two equal sections which are mirror images of each other.

The spaced condensing tubes 28 are disposed in a plurality of fan rows with each fan row being in a fan plane 36. Each fan plane 36 contains and extends radially from a straight connection along the cylindrical dome 26 between the flat axial ends 34 of the dome 26. Each condensing tube 28 extends from the dome 26 to a closed distal end. The invention is distinguished by the distal ends of each of the condensing tubes 28 being elongated along the associated fan plane 36 to define one of the fan rows in a fan shape. In other words, each fan row contains one elongated, fan-shaped condensing tube 28. The condensing tubes 28 in adjacent fan planes 36 terminate in an arch 38 extending concentrically about the center axis A at the flat axial ends 34 of the semi-cylindrical dome 26.

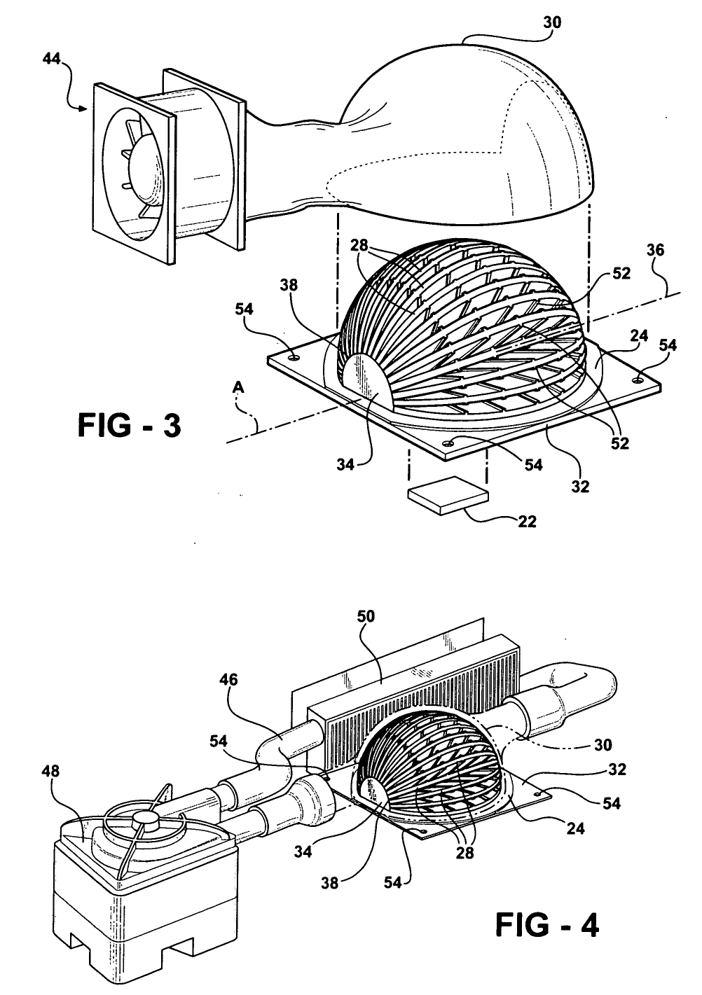

The condensing tubes 28 are spaced from one another in each associated fan plane 36. The space between next adjacent condensing tubes 28 decreases from the distal ends toward the straight connection along the cylindrical dome 26 between the flat axial ends 34 of the dome 26. The distal ends of the condensing tubes 28 extend along curved paths between the flat axial ends 34 in opposite directions from the transverse plane extending perpendicularly through the fan planes 36 and perpendicularly through the center axis A. FIGS. 1 and 3 show the fan planes 36 including their respective fan rows extending perpendicularly from the transverse plane. The adjacent fan rows and fan planes 36 converge toward one another in opposite directions from the transverse plane. This convergence is best illustrated in FIGS. 1 and 3 wherein the circumferential distance between the fan planes 36 decreases from the transverse plane to the end of the center axis A at the flat axial ends 34. The pattern of the elongated condensing tubes 28 resembles the erectile ribs of an igloo.

A charge port 40 extends from one of the flat axial ends 34. The charge port 40 provides an inlet for supplying refrigerant to the dome 26. Optionally, the charge port 40 could be disposed on the assembly at a position other than the flat axial ends 34 to supply the assembly with refrigerant. After the refrigerant is supplied to the dome 26, the charge port 40 is sealed by inserting a fuse plug 42 into the charge port 40, crimping the charge port 40 and then brazing the fuse plug 42. Alternatively, the charge port 40 could be sealed by inserting and then solely brazing the fuse plug 42.

The refrigerant is disposed on the bottom of the boiling chamber in the dome 26 for undergoing a liquid-to-vapor-to-condensate cycle in response to the heat generated by the electronic device 22. However, the assembly may be disposed in any orientation whereby the actual position of the refrigerant will be determined by gravity, so long as it covers or reaches a level above the position of the electronic device 22. The refrigerant can be, but is not limited to, a low boiling point fluid such as R-134A or one with a higher boiling point such as water, which is recommended.

The shroud 30 encloses the distal ends of the condensing tubes 28 in spaced relationship to the dome 26 and the distal ends for moving air over the condensing tubes 28 and over the dome 26. The shroud 30 and the distal ends of the condensing tubes 28 are disposed in a domed shape in spaced relationship to the dome.

FIGS. 2 and 3 show an air cooling assembly 44 including a fan powered by a motor. The air cooling assembly 44 is used to move air over the condensing tubes 28 and over the dome 26 to facilitate heat exchange. The air cooling assembly 44 can be used to push or pull air over the condensing tubes 28. FIG. 4 shows a liquid cooling assembly 46 including a piping system, a pumping assembly 48, a heat exchange system 50 and the cooling fluid. The liquid cooling assembly 46 is used to move the cooling fluid over the condensing tubes 28, over the dome 26, and under a closed shroud 30. In this case, a closed system would be necessary to avoid leakage.

At least one flow interrupter 52 is disposed on each elongated condensing tube 28. The flow interrupters 52 extend along the outer surfaces of the condensing tubes 28 radially downward from the distal ends toward the center axis A. The flow interrupters 52 enhance heat transfer by creating additional turbulence in the stream of cooling fluid that is forced over the condensing tubes 28 by the cooling assembly.

FIGS. 1, 3 and 4 show the boiler plate 32 defining at least one mounting hole 54. The mounting holes 54 are used to secure the assembly to a motherboard or other base via a fastening device such as, but not limited to, a bolt or screw.

Obviously, many modifications and variations of the present invention are possible in light of the above teachings. The invention may be practiced otherwise than as specifically described within the scope of the appended claims.

What is claimed is:

1. A heat exchanger assembly for cooling the electronic device comprising;
a boiler plate for disposition over the electronic device,
a dome having a center axis and disposed on said boiler plate and defining a domed boiling chamber curved axially along and laterally from said center axis,
a refrigerant disposed in said boiling chamber for undergoing a liquid-to-vapor-to-condensate cycle in response to the heat generated by the electronic device,
a plurality of spaced condensing tubes disposed in a plurality of fan rows and extending from said dome to distal ends,
each of said condensing tubes being in a fan plane containing and extending radially from said center axis,
a shroud enclosing said distal ends of said condensing tubes in spaced relationship to said dome for moving air through said condensing tubes and over said dome,
said shroud and said distal ends of said condensing tubes being disposed in a domed shape in spaced relationship to said dome, and
each of said condensing tubes being elongated along the associated fan plane to define one of said fan rows in a fan shape.

2. An assembly as set forth in claim 1 wherein said dome is semi-cylindrical about said center axis and extends between opposite flat axial ends.

3. An assembly as set forth in claim 2 wherein said distal ends of said condensing tubes extend along curved paths between said flat axial ends in opposite directions from a transverse plane extending perpendicularly through said fan plane and perpendicularly through said center axis.

4. An assembly as set forth in claim 3 wherein each condensing tube extends radially from a straight connection along said cylindrical dome between said flat axial ends of said dome.

5. An assembly as set forth in claim 4 wherein the space between next adjacent condensing tubes decreases from said distal ends to said straight connection.

6. An assembly as set forth in claim 5 wherein said adjacent fan rows and fan planes converge toward one another in opposite directions from said transverse plane along center axis to said flat axial ends of said dome.

7. An assembly as set forth in claim 6 wherein said condensing tubes in adjacent fan planes terminate in an arch extending concentrically about said center axis at said opposite flat axial ends of said semi-cylindrical dome.

8. An assembly as set forth in claim 2 including a charge port in one of said flat axial ends for charging said dome with said refrigerant.

9. An assembly as set forth in claim 8 including a fuse plug disposed in each of said charge ports for sealing each of said charge ports.

10. An assembly as set forth in claim 1 including a charge port for charging said assembly with said refrigerant.

11. An assembly as set forth in claim 1 wherein each of said condensing tubes includes at least one flow interrupter disposed on the outer surfaces of said condensing tubes and extending radially downward from said distal ends toward said center axis.

12. An assembly as set forth in claim 1 including a flange disposed on said boiler plate and surrounding said dome.

13. A heat exchanger assembly for cooling comprising;
a boiler plate,
a dome having a center axis and disposed on said boiler plate and defining a domed chamber curved axially along and laterally from said center axis,
a plurality of spaced condensing tubes disposed in a plurality of fan rows and extending from said chamber to distal ends,
each of said tubes being in a fan plane containing and extending radially from said center axis,
a shroud enclosing said distal ends of said condensing tubes in spaced relationship to said dome for moving air over said condensing tubes and over said dome,
said enclosure and said distal ends of said condensing tubes being disposed in a domed shape in spaced relationship to said dome, and
each of said condensing tubes being elongated along the associated fan plane to define one of said fan rows in a fan shape.
